(19) United States
(12) Patent Application Publication
(10) Pub. No.: US 2009/0090411 A1
(43) Pub. Date: Apr. 9, 2009

(54) Dye-Sensitized Solar Cell and Method of Manufacturing the Same

(75) Inventors: Won-Youl Choi, Gyeonggi-do (KR); Dae-Jin Yang, Seoul (KR); Hun Park, Daejeon (KR); Kyu-Shik Mun, Gyeonggi-do (KR)

Correspondence Address: MILLER, MATTHIAS & HULL, ONE NORTH FRANKLIN STREET, SUITE 2350, CHICAGO, IL, 60606, US

(73) Assignee: KANGNUNG NATIONAL UNIVERSITY INDUSTRY ACADEMJY CORPORATION GROUP, Gangwon-do (KR)

(21) Appl. No.: 11/935,753

(22) Filed: Nov. 6, 2007

(30) Foreign Application Priority Data
Oct. 5, 2007 (KR) 10-2007-0100579

(51) Int. Cl. H01L 31/04; C25D 3/54; B05D 1/18; B05D 1/00

(52) U.S. Cl. 136/252; 427/74; 205/200

(57) ABSTRACT

Provided are a dye-sensitized solar cell and a method of manufacturing the same, which includes: a lower electrode formed of a titanium metal or a titanium alloy; a titanium oxide electrode having a nanotube structure formed on the lower electrode; a metal oxide layer formed on the titanium oxide electrode along a step difference of the nanotube, having a larger band gap than titanium oxide, and having a dye adsorbed on a surface thereof; a counter electrode spaced a predetermined distance apart from the metal oxide layer; and an electrolyte filled between the metal oxide layer and the counter electrode. The titanium oxide electrode having a nanotube structure, which has a large specific surface area, may increase absorption of solar light and allow easy adsorption of a dye due to the metal oxide layer, thereby improving photo current and voltage characteristics of the solar cell.

### CROSS-REFERENCE TO RELATED APPLICATION

This application claims the benefit of Korean Patent Application No. 10-2007-0100579, filed Oct. 7, 2007, the disclosure of which is hereby incorporated herein by reference.

### BACKGROUND

1. Technical Field

A dye-sensitized solar cell and a method of manufacturing the same are disclosed. More particularly, a dye-sensitized solar cell is disclosed which forms a titanium oxide electrode in a nanotube structure having a large specific surface area which increases absorption of solar light and provides improved adsorption of the dye due to a metal oxide layer, thereby improving photo current and voltage characteristics of the solar cell. A method of manufacturing the same is also disclosed.

2. Description of the Related Art

Silicon or compound semiconductor-junction solar cells are being actively studied. In recent times, photoelectrochemical dye-sensitized solar cells using photosynthesis have been reported, and such dye-sensitized solar cells have attracted a large amount of attention in academic and industrial circles, due to high energy conversion efficiency of more than 11% and low production costs as compared to an amorphous silicon solar cell.

The dye-sensitized solar cell currently reported in academic circles uses a principle of injecting an electron generated from a dye toward an oxide semiconductor. Here, titanium oxide is known as the most effective oxide semiconductor material. However, there is a limit to an increase in energy conversion efficiency using only the titanium oxide.

Generally, a semiconductor electrode used in the dye-sensitized solar cell is manufactured using a colloidal solution of nanocrystalline oxide (diameter=˜15 to ˜20 nm) having high band gap energy. The particle size, shape, crystallinity, and surface state of the oxide, a method of forming a colloidal solution and dispersion ability have a significant effect on the electrode's performance, and thus research aimed at enhancing efficiencies by controlling these characteristics, creating a large number of electron-hole pairs and raising an electron transfer rate has been being progressing.

The biggest obstacle to higher light-electricity conversion efficiency in a nanocrystalline structure is electron transmission to an electrode across a particle network. For example, electrons created by light in a nanocrystalline film have to move to the electrode through a semiconductor particle network, however the electron has a high chance of recombination with an electrolyte.

### SUMMARY OF THE DISCLOSURE

A dye-sensitized solar cell is disclosed which may increase absorption of solar light due to a large specific surface area and energy conversion efficiency due to easy adsorption of the dye, and have excellent photo current-voltage characteristics.

A method of manufacturing a dye-sensitized solar cell is disclosed which may increase absorption of solar light due to a large specific surface area and high energy conversion efficiency due to easy adsorption of the dye, and which results in excellent photo current-voltage characteristics.

One disclosed dye-sensitized solar cell comprises: a lower electrode formed of a titanium metal or a titanium alloy; a titanium oxide electrode having a nanotube structure formed on the lower electrode; a metal oxide layer formed on the titanium oxide electrode along a step difference of the nanotube, having a larger band gap than titanium oxide, and having a dye adsorbed on a surface thereof; a counter electrode spaced a predetermined distance apart from the metal oxide layer; and an electrolyte filled between the metal oxide layer and the counter electrode.

The dye may be composed of a ruthenium (Ru) series dye which can absorb solar light and create an electron.

The titanium oxide electrode having a nanotube structure may have an inner diameter of the nanotube ranging from about 10 to about 300 nm.

The metal oxide layer may be formed of magnesium oxide (MgO), zinc oxide (ZnO), strontium oxide (SrO), niobium oxide (Nb₂O₃) or strontium titanate (SrTiO₃).

The metal oxide layer may be a magnesium oxide (MgO) layer smaller than a half of the inner diameter of the nanotube and having a thickness ranging from about 5 to about 50 nm.

The counter electrode may include: an upper transparent substrate formed of transparent glass or plastic; a conductive transparent electrode formed on a lower surface of the upper transparent substrate; and an upper electrode formed under the conductive transparent electrode.

The electrolyte may be a solution in which 1-hexyl-2,3-dimethyl-imidazolium iodide, iodine (I₂), lithium iodide (LiI) and 4-tert-butylpyridine (TBP) are dissolved in 3-methoxyacetonitrile to provide an electron to a dye by oxidation-reduction reaction.

One disclosed method of manufacturing a dye-sensitized solar cell comprises: forming a titanium oxide electrode having a nanotube on a titanium metal or a titanium alloy; forming a metal oxide layer having a larger band gap than titanium oxide on the titanium oxide electrode along a step difference of the nanotube; adsorbing a dye on the metal oxide layer; forming a counter electrode to be spaced a predetermined distance apart from the metal oxide layer; and filling an electrolyte between the metal oxide layer and the counter electrode.

The dye may be composed of a ruthenium (Ru) series dye which can absorb solar light and emit an electron.

The titanium oxide electrode having a nanotube structure may have an inner diameter of the nanotube ranging from about 10 to about 300 nm.

The metal oxide layer may be a magnesium oxide (MgO) layer smaller than a half of the inner diameter of the nanotube and having a thickness ranging from about 5 to about 50 nm.

The metal oxide layer may be formed of magnesium oxide (MgO), zinc oxide (ZnO), strontium oxide (SrO), niobium oxide (Nb₂O₃) or strontium titanate (SrTiO₃).

The forming of the counter electrode may comprise: preparing an upper transparent substrate formed of transparent glass or plastic; forming a conductive transparent electrode on a lower surface of the upper transparent substrate; and forming an upper electrode under the conductive transparent electrode.

The electrolyte may be a solution in which 1-hexyl-2,3-dimethyl-imidazolium iodide, iodine (I₂), lithium iodide (LiI) and 4-tert-butylpyridine (TBP) are dissolved in 3-methoxyacetonitrile to provide an electron to a dye by oxidation-reduction reaction.

The step of forming the titanium oxide electrode may include: preparing an electrochemical bath containing an electrolyte having fluorine (F) and arranging a cathode and an anode made of a titanium metal or a titanium alloy to be spaced apart from each other in the electrochemical bath; and forming a titanium oxide layer on the anode by applying a voltage to the anode and the cathode, and forming nanotubes layer downwardly from the surface of the titanium oxide layer.

The electrolyte may be sulfuric acid, orthophosphoric acid, oxalic acid, sodium sulfate or citric acid solution or a mixed solution thereof; or glycerol, ethylene glycol or a mixed solution thereof.

After forming the titanium oxide having the nanotube structure, the step of performing thermal treatment for 10 minutes to an hour at 450 to 550° C. may be carried out.

The forming the metal oxide layer having a larger band gap than titanium oxide on the surface of the titanium oxide electrode along the step difference of a nanotube may comprise: immersing the titanium oxide electrode having a nanotube structure into a container having a metal source solution; reducing pressure in the container to be lower than an air pressure; coating the titanium oxide electrode with the metal source solution for a predetermined time while maintaining a specific temperature; and thermally treating the titanium oxide electrode coated with the metal source solution to form a metal oxide layer on the surface of the titanium oxide electrode.

### BRIEF DESCRIPTION OF THE DRAWINGS

The above and other features will become more apparent to those of ordinary skill in the art upon review of the detailed description with reference to the attached drawings, wherein:

FIG. 1 is a schematic diagram illustrating a structure of a dye-sensitized solar cell using a nanotube titanium oxide electrode coated with metal oxide according to an exemplary embodiment;

FIG. 2 is a flowchart illustrating a method of manufacturing a nanotube titanium oxide electrode coated with metal oxide and a method of manufacturing a dye-sensitized solar cell using the same according to an exemplary embodiment;

FIG. 3 is a schematic diagram of equipment for performing anodizing;

FIG. 4 is a schematic diagram of dip-coating equipment for coating a titanium oxide electrode of a nanotube structure with a metal source solution;

FIG. 5 shows scanning electron microscopy (SEM) photographs of a cross-section and a surface of a nanotube titanium oxide electrode coated with magnesium oxide obtained by anodizing and dip-coating; and

FIG. 6 is a graph illustrating photo current-voltage characteristics of a dye-sensitized solar cell having a titanium oxide electrode having a nanotube structure which is not coated with magnesium oxide and a dye-sensitized solar cell having a titanium oxide electrode having a nanotube structure coated with magnesium oxide.

### DETAILED DESCRIPTION OF THE PRESENTLY PREFERRED EMBODIMENTS

The disclosed solar cells and methods of manufacturing solar cells will now be described more fully hereinafter with reference to the accompanying drawings, in which exemplary embodiments are shown. The disclosed cells and manufacturing methods may, however, be embodied in different forms and should not be construed as limited to the embodiments set forth herein. In the drawings, the thickness of layers and regions are exaggerated for clarity. In addition, when a layer is described to be formed on another layer or on a substrate, it may mean that the layer may be formed on the other layer or on the substrate, or a third layer may be interposed between the layer and the other layer or the substrate. Like numbers refer to like elements throughout the specification.

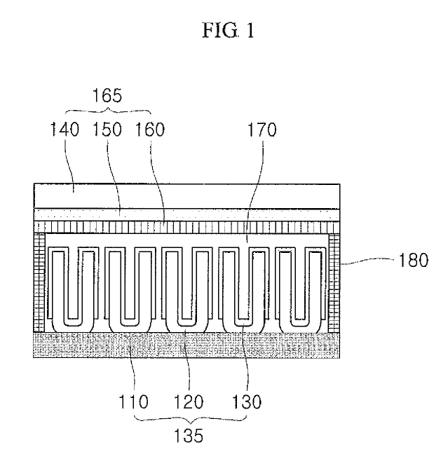

FIG. 1 is a schematic diagram illustrating a structure of a dye-sensitized solar cell using a nanotube titanium oxide electrode coated with metal oxide according to an exemplary embodiment.

Referring to FIG. 1, a disclosed dye-sensitized solar cell includes a lower electrode 110 formed of a metal including titanium or an alloy thereof, a titanium oxide electrode 120 having a nanotube structure formed on the lower electrode 110, a metal oxide layer 130 formed on the titanium oxide electrode 120 along a step difference of the nanotube and having a dye adsorbed thereon, a counter electrode 165 formed of a thin film on an upper transparent substrate 140 and corresponding to the lower electrode 110, and an electrolyte 170 filled between the lower electrode 110 and the counter electrode 165.

The lower electrode 110 may be formed of titanium metal or an alloy thereof. The nanotube may be grown downwardly (from the surface to the inside of titanium) up to about a maximum of about 160 μm in experimental conditions to be described below. An inner diameter of the nanotube ranges from about 10 to about 300 nm. Nano-size covers a range from about 1 to about 1000 nm, and a nanotube refers to a thing having a nano-sized inner diameter and a tube shape.

The thickness of the metal oxide layer 130 is determined to be less than a half of the inner diameter of the nanotube, and preferably 5 to 50 nm. The metal oxide layer 130 may include a magnesium oxide (MgO) layer, a zinc oxide (ZnO) layer, a strontium oxide (SrO) layer, a niobium oxide (Nb₂O₃) layer or a strontium titanate (SrTiO₃) layer which has a larger band gap than titanium oxide. Electrons excited to a conduction band of the titanium oxide electrode 120 cannot be transferred to the metal oxide layer 130 due to a large band gap of the metal oxide layer 130. The band gap of the metal oxide layer 130 functions as an energy barrier. For this reason, the metal oxide layer 130 having a larger band gap than the titanium oxide electrode 120 may improve photo current-voltage characteristics of the dye-sensitized solar cell.

The electrolyte 170 provides an electron to a dye using reduction-oxidation (redox) reaction. The electrolytes 170 may include a solution in which 1-hexyl-2,3-dimethyl-imidazolium iodide, iodine (I₂), lithium iodide (LiI) and 4-tert-butylpyridine (TBP) are dissolved in 3-methoxyacetonitrile.

The dye used herein is a material which can absorb solar light and effectively emit an electron, preferably a ruthenium (Ru) series material. Ru may make a complex together with an organic material such as cumarine, porphyrin, etc., which may also be used as a dye.

The counter electrode 164 includes an upper transparent substrate 140 formed of transparent glass or plastic, a conductive transparent electrode 150 formed on a lower surface of the upper transparent substrate 140 and an upper electrode 160 formed under the conductive transparent electrode 150.

The upper transparent substrate 140 may be formed of transparent glass or plastic which may increase optical conversion efficiency by transmitting solar light because of its high transparency. The transparent plastics include polyacrylate, polyimide, polyetherimide, polyarylate, cellulose acetate propinonate and polyethersulphone.

The conductive transparent electrode 150 may be formed of fluorine-doped tin oxide (FTO), indium oxide (In₂O₃), indium tin oxide (ITO) or indium zinc oxide (IZO), and preferably FTO because of its excellent film-forming characteristics and easily controllable resistance.

The conductive transparent electrode 150 serves as a buffer layer between the upper transparent substrate 140 and the upper electrode 160, and enhances adherence and electrical characteristics.

The upper electrode 160 may be formed of a noble metal such as platinum having excellent electric conductivity and high reflexibility. The upper electrode 160 reflects solar light reflected through the counter electrode 165 again, and thus may increase light collection efficiency of solar light.

A sealed part 180 is provided on a side between the lower electrode 110 and the counter electrode 165 (specifically, between the lower electrode and the upper electrode), and prevents an electrolyte from leaking therethrough. The sealed part 180 may be formed of a thermoplastic polymer.

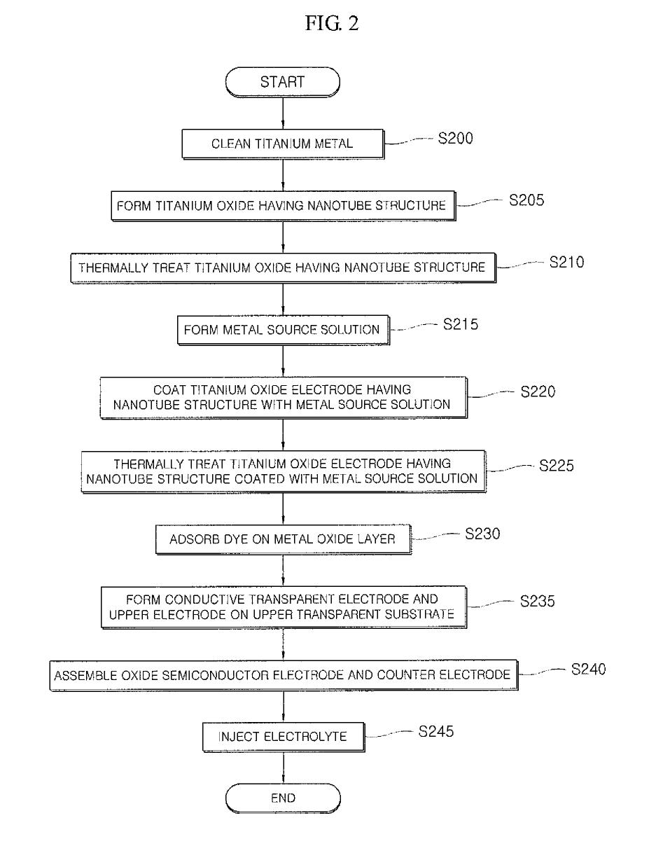

FIG. 2 is a flowchart illustrating a method of manufacturing a nanotube titanium oxide electrode coated with metal oxide and a method of manufacturing a dye-sensitized solar cell using the same according to an exemplary embodiment.

Referring to FIGS. 1 and 2, titanium metal (including a titanium alloy) to be used as the lower electrode 110 is immersed into a cleaning fluid, and cleaned for 5 min using an ultrasonic cleaner (S200). The titanium metal or titanium alloy may be a titanium or titanium alloy thin film formed on a transparent glass substrate, or a titanium metal bulk.

A nanotube-shaped titanium oxide electrode 120 is formed on the cleaned titanium metal surface (S205). The nanotube-shaped titanium oxide electrode may be formed by anodizing. As an electrolyte used for anodizing, sulphuric acid, orthophosphoric acid, oxalic acid, sodium sulfate or citric acid solution or fluorine (F)-added mixed solution thereof may be used. Furthermore, an organic electrolyte in which fluorine is added in glycerol, ethylene glycerol or a mixed solution thereof may be used. The anodizing is performed in such an electrolyte at 1 to 120 V and at 0 to 50° C. The diameter and length of the nanotube may be controlled depending on the electrolyte.

A method of forming titanium oxide having a nanotube by anodizing will now be described in detail.

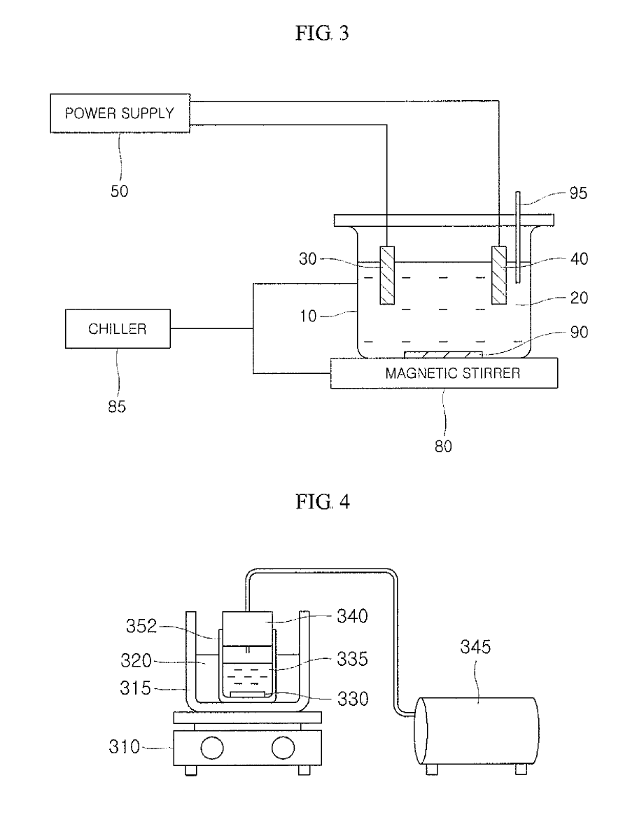

FIG. 3 is a schematic diagram of equipment for performing anodizing.

Critical parameters for anodizing may include an electrolyte, voltage, anodizing time, temperature, etc. The anodizing equipment includes an electrochemical bath 10, an electrolyte 20, an anode 30, a cathode 40, a power supply 50, a magnetic stirrer 80, a stirring magnetic bar 90, a chiller 85 and a thermometer 95 to control the critical parameters.

Titanium oxide (TiO₂) has an energy gap of 3.2 eV and is chemically and biologically stable, and thus is not easily corroded. The titanium oxide (TiO₂) may exist in three phases, such as an anatase phase, a rutile phase and a brookite phase. The anatase-phase titanium oxide is converted into the rutile-phase titanium oxide when being treated at a high temperature ranging from about over 1100° C. The titanium oxide (TiO₂) may be formed to have an anatase phase of a nanotube shape using anodizing according to an exemplary embodiment.

The anodizing equipment includes the electrochemical bath 10, the anode 30 to which a positive voltage is applied and a nanotube-shaped titanium oxide is formed, the cathode 40 to which a negative voltage is applied to supply an electron to a titanium (Ti) positive ion, the electrolyte 20 contained in the electrochemical bath 10, and the power supply 50 for applying a voltage to the anode 30 and the cathode 40. The anode 30 and the cathode 40 are spaced a predetermined distance apart from each other. The anode 30 uses the same titanium as that of desired nanotube-shaped titanium oxide (TiO₂).

In order to form nanotube-shaped titanium oxide (TiO₂), titanium is prepared, and mounted on the anode 30. The cathode 40 is formed of an acid-resistant metal, for example, platinum (Pt), tantalum (Ta), silver (Ag) or gold (Au). The anode 30 is set to be spaced a predetermined distance apart from the cathode 40 and be immersed into the electrolyte 20. The anode 30 and the cathode 40 are connected to the power supply 50 which is to apply a voltage or current thereto. The voltage applied to the anode 30 ranges from about 0 to about 300 V, and the voltage applied to the cathode 40 ranges from about 0 to about −300 V. The voltage difference between the anode 30 and the cathode 40 is properly controlled in consideration of the diameter and length of the nanotube to be formed.

In order to prevent an abrupt temperature increase due to an exothermic reaction during the anodizing process and to increase uniformity of electrolysis or chemical reaction over a metal layer, the chiller 85 is provided in the electrochemical bath 10, and the magnetic stirrer 80 and the stirring magnetic bar 90 are provided to easily cause anodizing by stirring the electrolyte. Furthermore, a thermometer such as a hot plate may be provided to keep the temperature in the electrochemical bath constant (not shown in the drawing).

The electrolyte 20 helps charged electrons or ions to be easily moved, thereby forming titanium oxide (TiO₂) on a titanium metal surface. A titanium metal ion (Ti⁴⁺) is dissolved in the electrolyte 20 at an interface between the electrolyte 20 and the titanium oxide, and the electrolyte 20 is bonded to oxygen (O²⁻) and hydroxyl (OH⁻) ions to form titanium oxide at an interface between the titanium oxide and the titanium metal.

When examining the anodizing process, a water (H₂O) molecule in the electrolyte 20 is electrolyzed into a hydrogen ion (H⁺) and a hydroxyl ion (OH⁻) as described in Reaction Formula 1.

H₂O→H⁺+OH⁻ Reaction Formula 1

The hydrogen ion (H⁺) moves to the cathode 40, bonded to an electron between the electrolyte 20 and the surface of the cathode 40, and then emitted in the form of hydrogen (H₂).

The hydroxyl ion (OH⁻) moves to the anode 30 and then are separated from an oxygen ion (O²⁻) and a hydrogen ion (H⁺) in a natural oxide layer formed on the surface of the anode 30 (titanium). Here, the oxygen ion (O²⁻) separated therefrom passes through the natural oxide layer to react with a titanium ion (Ti⁴⁺) between the natural oxide layer and the titanium, which results in titanium oxide (TiO₂) as in the following Reaction Formula 2.

Ti⁴⁺+2O²⁻→TiO₂ Reaction Formula 2

Also, a hydrogen ion (H⁺) reacts with the titanium oxide (TiO₂) and the bonding between titanium (Ti) and oxygen is partially cut, thereby forming hydroxide, which is dissolved in the electrolyte 20. That is, oxide etching occurs on the surface between the titanium oxide (TiO₂) and the electrolyte 20. As such, the titanium oxide (TiO₂) is formed at an interface between the natural oxide layer and the titanium layer, and etched at the surface between the titanium oxide (TiO₂) and the electrolyte 20, resulting in an anatase-phase titanium oxide (TiO₂) having a nano-sized pore. While an exact thesis on a pore formation process has not been reported yet, it is understood that local overcurrent occurs in the titanium oxide (TiO₂), which causes an exothermic reaction, thereby locally accelerating oxide etching by the electrolyte, and thus the pore is formed.

Consequently, the reaction may be summarized in Reaction Formula 3 as follows.

Ti+2H₂O→TiO₂+4H⁺+4e⁻ Reaction Formula 3

The water molecule in the electrolyte encounters Ti metal in the anode, thereby forming the titanium oxide (TiO₂) as in Reaction Formula 3.

The titanium oxide (TiO₂) formed as such is dissociated by a small amount of fluorine ions (F⁻) contained in the electrolyte as in Reaction Formula 4.

TiO₂+6F⁻+4H⁺→[TiF₆]²⁻+2H₂O Reaction Formula 4

The dissociation occurs in the entire titanium oxide (TiO₂) to generate a nano-sized nanotube. Also, as the anodizing time increases, the oxidation of Reaction Formula 3 and the dissociation of Reaction Formula 4 may simultaneously occur, thereby obtaining titanium oxide (TiO₂) having a nanotube. The inner diameter of the nanotube ranges from about 10 to about 300 nm.

The thickness of the titanium oxide (TiO₂) is determined by the following formula depending on a voltage (Uₐ) supplied from the power supply 50 and the electric field strength (Ea) of the oxide layer.

dₒₓ=Uₐ/Eₐ=Kₐ·Uₐ, Formula

wherein Kₐ is an anodizing coefficient.

When nanotube-shaped titanium oxide (TiO₂) is formed, the diameter and length of the nanotube may be appropriately controlled by concentration of the electrolyte, the applied voltage, processing time and temperature ranging from about the electrochemical bath.

The titanium oxide having a nanotube structure formed by anodizing is crystallized by thermal treating to form a titanium oxide electrode 120 having a nanotube structure (S210). Specifically, titanium oxide having a nanotube structure is increased in temperature at a rate of from about 2 to two about 5° C. per minute in an air atmosphere, and then naturally cooled down after thermal treatment for a time interval ranging from about 10 min to 1 hour at a temperature ranging from about 450 to about 550° C.

A metal source solution is prepared to coat the titanium oxide electrode 120 having a nanotube structure with metal oxide (S215). For example, in the case of magnesium oxide (MgO), a magnesium coating solution is prepared by diluting a magnesium acetate solution (Mg(CH₃COO)₂.4H₂O) in distilled water or ethanol solvent. Here, the magnesium acetate solution (Mg(CH₃COO)₂.4H₂O) is diluted to a concentration ranging from about 0.01 to about 0.1M.

In order to improve efficiency of the solar cell, the titanium oxide electrode 120 is coated with the metal source solution (S220). The coating of a metal source solution may be performed by spin-coating or dip-coating the titanium oxide electrode having a nanotube structure. In the exemplary embodiment, a method of forming a metal oxide layer 130 using dip coating will be described.

FIG. 4 is a schematic diagram of dip coating equipment for coating a titanium oxide electrode having a nanotube structure with a metal source solution.

Referring to FIG. 4, the dip coating equipment used herein includes a hot plate 310 for temperature control, a beaker 315 containing distilled water to maintain uniform temperature, distilled water 320, a beaker 325 containing a metal source solution, a titanium oxide electrode specimen having a nanotube structure 330, a metal source solution 335, and a silicon plug 340 and a vacuum pump 345 which are used to make vacuum environment. A dip coating process is performed by reducing pressure in the beaker 325 containing the titanium oxide electrode specimen 330 having a nanotube structure and the metal source solution 355 using the vacuum pump 345, and dipping the titanium oxide electrode specimen 330 in the metal source solution 335 for a time interval ranging from about 10 to about 60 minutes at a temperature ranging from about 25 to about 90° C.

The titanium oxide electrode 120 having a nanotube structure coated with the metal source solution is thermally treated so as to form a metal oxide layer (S225). The metal oxide layer 130 may be formed to a thickness ranging from about 5 to about 50 nm in consideration of the diameter of the nanotube. The metal oxide layer 130 is formed on the surface of the titanium oxide electrode 120 having a nanotube structure along a step difference of the nanotube. An organic element of the metal source solution is pyrolyzed by the thermal treatment, and thus the metal source solution is converted into metal oxide. The thermal treatment may be performed under the same conditions as the thermal treatment for crystallizing the titanium oxide electrode 120 having a nanotube structure. To be specific, the titanium oxide electrode 120 having a nanotube structure coated with the metal source solution is increased in temperature from about 2 to about 50° C. per minute in an air atmosphere, and naturally cooled down after the thermal treatment for a time interval ranging from about 10 minutes to about 1 hour at a temperature ranging from about 450 to about 550° C. Thereby, an oxide semiconductor electrode 135 including the lower electrode 110, the titanium oxide electrode 120 having a nanotube structure and the metal oxide layer 130 is completed.

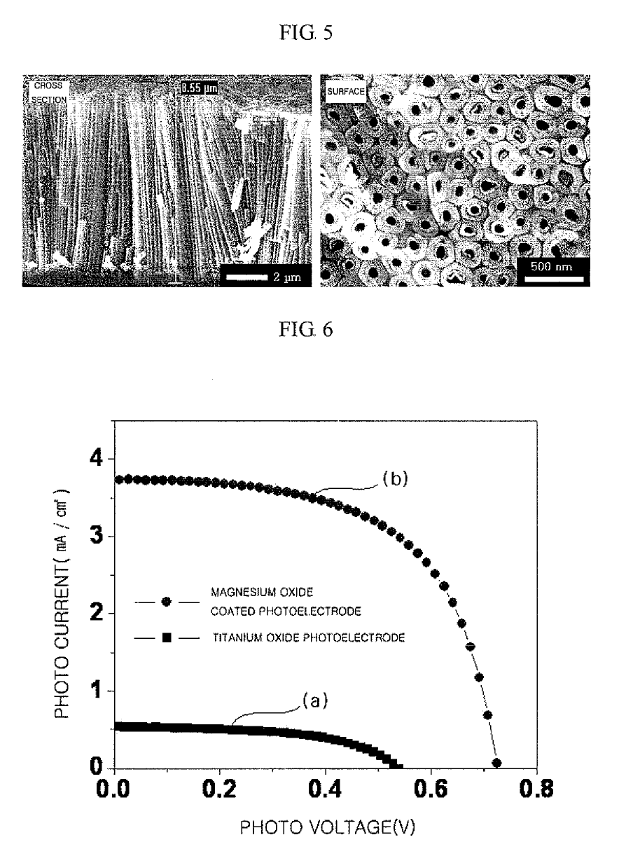

FIG. 5 is scanning electron microscopy (SEM) photographs illustrating a cross-section and a surface of a nanotube titanium oxide electrode coated with a metal oxide layer obtained by anodizing and dip-coating. FIG. 5 illustrates an array structure of the nanotube titanium oxide electrode coated with magnesium oxide, the array having a length of about 8.55 μm and a diameter of about 150 nm. In FIG. 5, a photograph on the left side illustrates a cross-section of the nanotube titanium oxide electrode coated with magnesium oxide, and a photograph on the right side illustrates a surface of the titanium oxide electrode coated with magnesium oxide.

A nanotube titanium oxide electrode 120 coated with magnesium oxide of FIG. 5 is formed by anodizing and dip-coating under the following conditions. An ethylene glycol organic solution is used as an electrolyte for anodizing, and 0.25 w % NH₄F is used as a fluoride source solution. In order to form a nanotube, a voltage difference between the anode 30 and the cathode 40 is maintained at about 60V, and the anodizing is performed for about 3 hours at about 30° C. In order to crystallize the titanium oxide electrode, the temperature is increased at about 5° C. per minute, and the titanium oxide electrode is thermally treated for about 30 minutes at about 500° C. and then naturally cooled down. The magnesium source solution is prepared by diluting a 0.1M magnesium acetate solution with an ethanol solvent. The dip coating process is performed for about 30 minutes at about 50° C. In order to form a magnesium oxide layer, the temperature is increased at a rate of about 50° C. per minute, and the magnesium oxide layer is thermally treated for about 30 minutes at about 500° C. and then naturally cooled down.

It can be seen from FIG. 5 that the titanium oxide electrode 120 having a nanotube structure is well formed.

The nanotube titanium oxide electrode 120 has regularly arranged electrodes in a vertical direction. Therefore, electron transmission in the titanium oxide electrode 120 is rapidly performed, and efficiency of the solar cell may increase.

Due to the tube-shaped electrode structure, as compared with a conventional nanocrystalline electrode formed in a random structure, a polymer having high viscosity and a solid electrolyte may be easily penetrated, thereby enhancing long-term stability of a dye-sensitized solar cell.

In the current experiment, the titanium oxide electrode 120 may be formed to a maximum length of about 160 μm and a maximum diameter of about 300 nm, and a metal oxide layer 130, i.e., a magnesium oxide layer may be formed to a maximum thickness of about 50 nm by changing parameters of the anodizing and dip coating processes. Such changes in diameter and length of the nanotube may lead to the improvement of the efficiency of the dye-sensitized solar cell.

A dye is adsorbed on the metal oxide layer 130 (S230). The dye molecule can be adsorbed by impregnating an oxide semiconductor electrode 135 over 24 hours in a solution (˜0.01 to 0.1 mM) in which a ruthenium (Ru) series dye molecule is dissolved.

By controlling conditions for anodizing and dip coating shown in the embodiment, a specific surface area of the nanotube structure may be controlled, and thus an adsorption amount of the dye molecule may increase. Particularly, the metal oxide layer 130 may increase the dye adsorption amount compared to an electrode formed of only titanium oxide, which may result in more photoelectrons and an increase in energy conversion efficiency of the solar cell.

A counter electrode 165 is prepared (S235). The counter electrode 165 includes an upper transparent substrate 140 formed of transparent glass or plastic, and a conductive transparent electrode 150 formed of a FTO material on one surface of the upper transparent substrate 140. The conductive transparent electrode 150 serves as a buffer layer between the upper transparent substrate 140 and the upper electrode 160, and enhances adherence and electrical characteristics. The conductive transparent electrode 150 may be formed by chemical vapor deposition (CVD), sputtering or electrochemical deposition. The conductive transparent electrode 150 may be controlled in thickness according to the size of the solar cell, and is preferably formed to a sickness ranging from about 500 Å to about 50 nm.

The glass substrate 140 on which the conductive transparent electrode 150 is deposited is punched to make a hole having an electrolyte 170 therein, and then cleaned.

The upper electrode 160 is formed of platinum on the surface of the conductive transparent electrode 150. The upper electrode 160 may be formed by spin coating the surface of the conductive transparent electrode 150 with a platinum solution (˜0.05M) and thermally treating the coated result. The thermal treatment may be performed in the same condition as the thermal treatment performed for crystallizing the titanium oxide electrode having a nanotube structure. The upper electrode 160 may be controlled in thickness according to the size of the solar cell, and is preferably formed to a thickness ranging from about 500 Å to about 50 nm.

The counter electrode 165 and the oxide semiconductor electrode 135 are arranged to face each other, and thermoplastic polymers are laid down at edges of the space between the both electrodes, and then the space is sealed by applying heat and pressure. The sealed part 180 may be controlled in thickness according to the size of the solar cell, and is preferably formed to a thickness ranging from about 25 to about 60 μm.

The electrolyte 170 is injected through the hole in the counter electrode 165 (S245). A light vacuum condition is made inside the titanium oxide electrode having a nanotube structure to completely infiltrate the electrolyte thereto. The electrolyte 170 may be a solution in which 0.1 to 1.0M 1-hexyl-2,3-dimethyl-imidazolium iodide, 0.01 to 0.1M iodine (I₂), 0.1M lithium iodide (LiI) and 0.1 to 1.0M 4-tert-butylpyridine (TBP) are dissolved in 3-methoxyacetonitrile. After being filled with the electrolyte 170, the hole is sealed with a thermoplastic polymer and a cover glass.

The following experimental examples in detail are intended to provide those skilled in the art working examples and are not be construed as limiting the scope of this disclosure.

### EXPERIMENTAL EXAMPLE 1

By a method in which steps S215, S220 and S225 were omitted from the embodiment, a solar cell was manufactured using a titanium oxide electrode which was not coated with magnesium oxide, and its photo current-voltage characteristics were measured. FIG. 6(a) shows the photo current-voltage characteristics of a dye-sensitized solar cell manufactured using a nanotube titanium oxide electrode having a thickness of 8.55 μm which was measured under the condition of AM 1.5, 100 mW/cm², and Table 1 shows photoelectrical characteristic results calculated from FIG. 6(a).

TABLE 1

| | Short-circuit | | Energy |
|---|---|---|---|
| Open-circuit | Current Density | | Conversion |
| Voltage (Voc) | (Jsc, mA/cm²) | Fill Factor | Efficiency (%) |
| 0.54 | 0.54 | 54.23 | 0.16 |

The solar cell according to Experimental Example 1 was manufactured under conditions as follows. An ethylene glycol organic solution was used as an electrolyte to perform anodizing, and 0.25 wt % NH₄F was used as a fluoride source solution. In order to form a nanotube, a voltage difference between an anode 30 and a cathode 40 was maintained at about 60V, and the anodizing was performed for 3 hours at 30° C. In order to crystallize a titanium oxide electrode, after increasing the temperature at 50° C. per minute, thermal treatment was performed for 30 minutes at 500° C., and then the titanium oxide electrode was naturally cooled down. A counter electrode 165 was manufactured by forming a 10 nm conductive transparent electrode 150 formed of FTO on a glass substrate 140 using chemical-mechanical deposition, and a 10 nm upper electrode formed of platinum on a surface of the conductive transparent electrode 150 using spin coating. A solution in which 0.1M 1-hexyl-2,3-dimethy-imidazolium iodide, 0.01M iodine (I₂), 0.1M lithium iodide (LiI) and 0.1M 4-tert-butylpyridine (TBP) were dissolved in 3-methoxyacetonitrile was used as an electrolyte 170.

### EXPERIMENTAL EXAMPLE 2

According to another exemplary embodiment, a solar cell was manufactured using a titanium oxide electrode coated with magnesium oxide, and its photo current-voltage characteristics were measured. FIG. 6(b) shows the photo current-voltage characteristics of a dye-sensitized solar cell manufactured using the magnesium oxide-coated nanotube titanium oxide electrode having a thickness of 8.55 μm which was measured under the condition of AM 1.5, 100 mW/cm², and Table 2 shows photoelectrical characteristic results calculated from FIG. 6(b). The measurement condition is the same as that of Experiment Example 1, and the results are shown in Table 2.

TABLE 2

| | Short-circuit | | |
|---|---|---|---|
| Open-circuit Voltage | Current Density | Fill | Energy Conversion |
| (Voc) | (Jsc, mA/cm²) | Factor | Efficiency (%) |
| 0.73 | 3.73 | 59.58 | 1.61 |

The solar cell according to Experimental Example 2 was manufactured under conditions as follows. An ethylene glycol organic solution was used as an electrolyte to perform anodizing, and 0.25 wt % NH₄F was used as a fluoride source solution. In order to form a nanotube, a voltage difference between an anode 30 and a cathode 40 was maintained at about 60V, and the anodizing was performed for 3 hours at 30° C. In order to crystallize a titanium oxide electrode, after increasing the temperature at 50° C. per minute, thermal treatment was performed for 30 minutes at 500° C., and then the titanium oxide electrode was naturally cooled down. A magnesium source solution was manufactured by diluting a 0.1M magnesium acetate solution (Mg(CH₃COO)₂.4H₂O) with an ethanol solvent. A dip coating process was performed for 30 minutes at 50° C. In order to form a magnesium oxide layer, after increasing the temperature at 50° C. per minute, thermal treatment was performed for 30 minutes at 500° C., and then the magnesium oxide layer was naturally cooled down. A counter electrode 165 was manufactured by forming a 10 nm conductive transparent electrode 150 formed of FTO on a glass substrate 140 using chemical-mechanical deposition, and a 10 nm upper electrode formed of platinum on a surface of the conductive transparent electrode 150 using spin coating. A solution in which 0.1M 1-hexyl-2,3-dimethy-imidazolium iodide, 0.01M iodine (I₂), 0.1M lithium iodide (LiI) and 0.1M 4-tert-butylpyridine (TBP) were dissolved in 3-methoxyacetonitrile was used as an electrolyte 170.

As compared with Table 1, it may be seen from Table 2 that the open-circuit voltage, the short-circuit current density and fill factor are greatly increased by magnesium oxide coating, which results in an increase in energy conversion efficiency 10 times higher than Experimental Example 1, which was not coated with magnesium oxide.

A disclosed dye-sensitized solar cell employs a titanium oxide electrode having a nanotube structure coated with metal oxide, and thus has advantages and effects as follows.

The nanotube titanium oxide electrode coated with metal oxide has an electrode structure regularly and vertically arranged compared to a nanoparticle synthesized at a high temperature. Thus, electron transmission in the titanium oxide electrode is rapidly performed, and may increase efficiency of the solar cell.

Due to the tube-shaped electrode structure, compared to a conventional nanocrystalline electrode formed in a random structure, a polymer having high viscosity and a solid electrolyte may be easily penetrated into the electrode, thereby improving long-term stability of the dye-sensitized solar cell.

By controlling conditions of anodizing and dip coating, a specific surface area of the nanotube structure may be controlled, which may result in an increase in an adsorption amount of the dye molecules. Particularly, coating the nanotube structure with metal oxide may greatly improve a dye adsorption amount compared to an electrode made of only titanium oxide, and thus may generate more photoelectrons, and increase energy conversion efficiency of the solar cell.

The titanium oxide electrode having a large specific surface area is formed in a nanotube structure, thereby increasing absorption of solar light and easily adsorbing the dye on the metal oxide layer to improve photo current and voltage characteristics of the solar cell.

While certain exemplary embodiments have been disclosed, it will be understood by those skilled in the art that various changes in form and details may be made therein without departing from the spirit and scope of this disclosure as defined by the appended claims.

What is claimed is:

1. A dye-sensitized solar cell comprising:
a lower electrode comprising a material selected from the group consisting of titanium and titanium alloy;
a titanium oxide electrode comprising a nanotube structure formed on the lower electrode;
a metal oxide layer formed on the titanium oxide electrode that has a larger band gap than titanium oxide and that has a dye adsorbed on a surface thereof;
a counter electrode spaced a predetermined distance apart from the metal oxide layer; and
an electrolyte sandwiched between the metal oxide layer and the counter electrode.

2. The dye-sensitized solar cell according to claim 1, wherein the dye is composed of a ruthenium (Ru) series dye which can absorb solar light and emit an electron.

3. The dye-sensitized solar cell according to claim 1, wherein the titanium oxide electrode having a nanotube structure has an inner diameter ranging from about 10 to about 300 nm.

4. The dye-sensitized solar cell according to claim 1, wherein the metal oxide layer comprises a material selected from the group consisting of magnesium oxide (MgO), zinc oxide (ZnO), strontium oxide (SrO), niobium oxide (Nb₂O₃) and strontium titanate (SrTiO₃).

5. The dye-sensitized solar cell according to claim 1, wherein the metal oxide layer comprises a magnesium oxide (MgO) layer thinner than about one half of an inner diameter of the nanotube structure and having a thickness ranging from about 5 to about 50 nm.

6. The dye-sensitized solar cell according to claim 1, wherein the counter electrode comprises:
an upper transparent substrate comprising glass or plastic;
a conductive transparent electrode formed on a lower surface of the upper transparent substrate; and
an upper electrode formed under the conductive transparent electrode.

7. The dye-sensitized solar cell according to claim 1, wherein the electrolyte comprises a solution comprising 1-hexyl-2,3-dimethyl-imidazolium iodide, iodine (I₂), lithium iodide (LiI) and 4-tert-butylpyridine (TBP) dissolved in 3-methoxyacetonitrile to provide an electron to a dye by an oxidation-reduction reaction.

8. A method of manufacturing a dye-sensitized solar cell comprising:
forming a titanium oxide electrode having a nanotube structure on a material selected from the group consisting enough titanium and a titanium alloy;
forming a metal oxide layer having a larger band gap than titanium oxide on the titanium oxide electrode;
adsorbing a dye on the metal oxide layer;
forming a counter electrode to be spaced a predetermined distance apart from the metal oxide layer; and
filling an electrolyte between the metal oxide layer and the counter electrode.

9. The method according to claim 8, wherein the dye comprises a ruthenium (Ru) series dye which can absorb solar light and emit an electron.

10. The method according to claim 8, wherein the nanotube structure has an inner diameter ranging from about 10 to about 300 nm.

11. The method according to claim 8, wherein the metal oxide layer is thinner than about one half of an inner diameter of the nanotube structure and is formed to a thickness ranging from about 5 to about 50 nm.

12. The method according to claim 8, wherein the metal oxide layer comprises a material selected from the group consisting of magnesium oxide (MgO), zinc oxide (ZnO), strontium oxide (SrO), niobium oxide (Nb₂O₃), and strontium titanate (SrTiO₃).

13. The method according to claim 8, wherein the forming of the counter electrode comprises:
preparing an upper transparent substrate formed of transparent glass or plastic;
forming a conductive transparent electrode on a lower surface of the upper transparent substrate; and
forming an upper electrode under the conductive transparent electrode.

14. The method according to claim 8, wherein the electrolyte comprises a solution comprising 1-hexyl-2,3-dimethyl-imidazolium iodide, iodine (I₂), lithium iodide (LiI) and 4-tert-butylpyridine (TBP) dissolved in 3-methoxyacetonitrile to provide an electron to a dye by oxidation-reduction reaction.

15. The method according to claim 8, wherein the forming the titanium oxide electrode comprises:
preparing an electrochemical bath containing an electrolyte having fluorine (F) and arranging a cathode and an anode made of a titanium metal or a titanium alloy to be spaced apart from each other in the electrochemical bath; and
forming a titanium oxide layer on the anode by applying a voltage to the anode and the cathode, and forming nanotubes layer downwardly from the surface of the titanium oxide layer.

16. The method according to claim 15, wherein the electrolyte comprises at least one material selected from the group consisting of sulfuric acid, orthophosphoric acid, oxalic acid, sodium sulfate, citric acid, glycerol, ethylene glycol and mixtures thereof.

17. The method according to claim 15, further comprising:
after forming the titanium oxide having a nanotube structure,
thermally treating the titanium oxide for a time interval ranging from about 10 minutes to about 1 hour at a temperature ranging from about 450 to about 550° C. to at least partially crystallize the titanium oxide.

18. The method according to claim 8, wherein forming a metal oxide layer having a larger band gap than titanium oxide on the surface of the titanium oxide electrode comprises the steps of:
immersing the titanium oxide electrode having a nanotube structure into a container having a metal source solution;
reducing pressure in the container to be lower than an air pressure;
coating the titanium oxide electrode with the metal source solution for a predetermined time while maintaining a specific temperature; and
thermally treating the titanium oxide electrode coated with the metal source solution to form a metal oxide layer on the surface of the titanium oxide electrode.
